(19) United States
(12) Patent Application Publication
(10) Pub. No.: US 2016/0013559 A1
(43) Pub. Date: Jan. 14, 2016

(54) BRIDGELESS ANTENNA, AND METHOD OF MANUFACTURE

(71) Applicant: Transponder Concepts LLC, Natick, MA (US)

(72) Inventors: Robert YEWEN, Brampton (CA); Ken HUTCHINS, Natick, MA (US)

(21) Appl. No.: 14/681,994

(22) Filed: Apr. 8, 2015

Related U.S. Application Data
(60) Provisional application No. 61/977,017, filed on Apr. 8, 2014.

(51) Int. Cl. H01Q 9/30; H01Q 1/38; H01Q 9/04; H05K 3/10

(52) U.S. Cl. CPC H01Q 9/30; H05K 3/10; H01Q 1/38; H01Q 9/04

(57) ABSTRACT

A tag having: circuitry; an antenna assembly comprising a first conductive trace with one antenna lead connected to said circuitry and another antenna lead free of any permanent physical coupling and a second conductive trace with one antenna lead connected to said circuitry and another antenna lead free of any permanent physical connection, to form a tag with a bridgeless antenna assembly.

### CROSS-REFERENCE TO RELATED APPLICATIONS

This application claims the benefit of priority to U.S. Provisional Application Ser. No. 61/977,017, filed on Apr. 8, 2014.

### FIELD OF THE INVENTION

The present invention relates to wireless communication, more particularly, it relates to a printed flexible antenna for use in radio frequency identification (RFID) and near-field communication (NFC) systems, and a method of manufacture thereof.

### DESCRIPTION OF THE RELATED ART

The demand for flexible NFC/RFID tags has increased tremendously due to the requirements of automatic identification, tracking, and monitoring in the areas of retail supply chain, military supply chain, pharmaceutical tracking and management, access control, sensing and metering applications, parcel and document tracking, automatic payment solutions, asset tracking, real time location systems (RTLS), automatic vehicle identification, and livestock or pet tracking. RFID systems can be classified into three different types by operating methods which are: passive; semi-active; and active. While there are different operating frequencies and standards in different countries, the common operating frequencies include: 125 kHz in the LF band, 13.56 MHz in the HF band, 915 MHz in the UHF band, 2.4 GHz and 5.8 GHz in the SHF band.

The spread of NFC/RFID technology has been hampered by the price of NFC/RFID tags, a problem rooted in the manufacturing process of tags. There are several prior art production processes for antennas for RFID tags or NFC tags. One such process employs copper etching or aluminum etching in the RFID antenna production process. However, the etching production process has a variety of drawbacks, such as a substantial raw material waste and environmental pollution, and it is also very costly. Another production process is silver ink printing which uses screen printing, flexographic printing, gravure printing, ink-jet printing method to print the antenna pattern on the substrate such as PET with costly silver ink. Yet another production process is electroless plating, which uses screen printing, flexographic printing, gravure printing, ink-jet printing methods to print the antenna pattern on the substrate with catalyst ink, and then deposit copper metal onto the catalytic layer by electroless plating equipment to form the antenna. One drawback of this process is the substantial time required for sufficient copper metal of a suitable thickness to form the antenna. As such, the relatively slow electroless plating speed makes this process non-ideal for mass production of antennas or tags. Electro-plating is yet another prior art production process, and it uses screen printing, flexographic printing, gravure printing, ink-jet printing method to print the antenna pattern on the substrate with conductive ink, then to deposit copper metal onto the conductive layer by electro plating equipment to form an antenna. Once again, this process is costly.

In addition, current NFC/RFID tags typically comprise bridged antennas fabricated by combining several separately manufactured components with the use of adhesives or crimping. This manufacturing process also requires a dielectric crossover and a conductive link to bridge the ends of an antenna coil. Such techniques result in substantial yield reduction, and may also interfere with conductivity. Therefore, these antennas are relatively expensive to manufacture due to the increased costs of materials and the multiple step manufacturing process of bridged antennas.

It is an object of the present invention to mitigate or obviate at least one of the above-mentioned disadvantages.

### SUMMARY OF THE INVENTION

In one of its aspects, there is provided a method of manufacture of a tag, the method comprising the steps of:
providing a substrate having a surface;
in one pass, depositing on said surface conductive material to form an antenna assembly having a first conductive trace with one antenna lead connected to electronic circuitry and another antenna lead free of any coupling, and a second conductive trace with one antenna lead connected to said electronic circuitry and another antenna lead free of any coupling.

In another of its aspects, there is provided an antenna comprising:
a substrate having a surface;
a bridgeless antenna assembly on said surface, and said bridgeless antenna assembly comprising a first conductive trace with one antenna lead for connection to circuitry and another antenna lead free of any permanent physical coupling, and a second conductive trace with one antenna lead for connection to said circuitry and another antenna lead free of any permanent physical connection.

In another of its aspects, there is provided a tag having:
circuitry;
an antenna assembly comprising a first conductive trace with one antenna lead connected to said circuitry and another antenna lead free of any permanent physical coupling and a second conductive trace with one antenna lead connected to said circuitry and another antenna lead free of any permanent physical connection; and
wherein capacitive coupling between said first conductive trace and said second conductive trace and said substrate completes a circuit formed of said first conductive trace, second conductive trace and said circuitry to obviate a physical electrical connection from said leads free of any coupling to said circuitry, thereby resulting in said tag having a bridgeless antenna assembly.

In yet another of its aspects, there is provided a communication system, comprising:
a tag having a circuit chip and a tag antenna element comprising a first conductive trace with one antenna lead connected to said circuitry and another antenna lead free of any permanent physical coupling and a second conductive trace with one antenna lead connected to said circuitry and another antenna lead free of any permanent physical coupling to form a bridgeless tag antenna;
a tag reader with circuitry having a reader antenna, and a processing unit; and whereby
said bridgeless tag antenna and reader antenna are adapted to form a capacitive interface or inductive interface when said tag is positioned proximate said reader and to exchange data signals therebetween.

In yet another of its aspects, there is provided a method of manufacture of a method of manufacture of an antenna, the method comprising the steps of:
providing a substrate having a surface;
depositing in one pass a conductive pattern on said surface, said conductive pattern having a first conductive trace with a first antenna lead for coupling to a component and a second connection-free antenna lead; and having a second conductive trace with a first antenna lead for coupling to said component and a second connection-free antenna lead;
wherein capacitive coupling between said first conductive trace and said second conductive trace and said substrate completes a circuit formed of said first conductive trace, second conductive trace and said component to obviate a physical electrical connection from said second connection-free antenna leads to said component, thereby resulting in a bridgeless antenna assembly.

Advantageously, a bridgeless antenna brings several benefits to the manufacturing of NFC/RFID tags, such as the elimination of extra steps required when printing bridges using dielectric masks and conductive inks. The reduced step manufacturing process may be employed to fabricate a bridgeless antenna using any one of the following techniques: printed conductive inks; screens; transfer films and selective metalized, among others.

The geometry selection, size and shape of the printed conductive elements are selected in accordance with a desired resonant frequency and application. In one embodiment, the conductive elements consist of various connection paths between various shapes of spiral printed conductors and strategically placed printed plates to provide capacitive coupling for a chosen substrate, or laminated and aligned for continuance of the circuit. These inductive and capacitive printed circuit elements are strategically placed to interact with each other to form the required antenna resonance at the target RFID or NFC desired frequency as the antenna system's ideal resonance for the application.

In addition the balanced geometric planar printed conductive pattern of inductive and capacitive printed elements provide manufacturing economy and ideal performance and the possibility for a single pass etched or deposition applied conductive circuit. Further, increased balance and quality factor (Q), and also the ability also to tune the resonant frequency through the unique chemical properties of laminated substrates as well as other single pass printed flexible geometric capacitive and resistive elements allows for a plurality of unique tag solutions to be realized, through multiple single pass circuit templates or single pass printing runs, and provides various methods for printing the conductive patterns.

### BRIEF DESCRIPTION OF THE DRAWINGS

Several exemplary embodiments of the present invention will now be described, by way of example only, with reference to the appended drawings in which:

FIG. 1 is a view of an exemplary tag having a scalar bridgeless antenna, in one embodiment;

FIG. 2 shows a schematic diagram of a circuit of the tag of FIG. 1;

FIG. 3 shows a flow diagram with exemplary steps for a method of manufacturing the tag of FIG. 1; and

FIG. 4 is a view of an exemplary bridgeless antenna assembly.

### DETAILED DESCRIPTION OF EXEMPLARY EMBODIMENTS

The detailed description of exemplary embodiments of the invention herein makes reference to the accompanying block diagrams and schematic diagrams, which show the exemplary embodiment by way of illustration and its best mode. While these exemplary embodiments are described in sufficient detail to enable those skilled in the art to practice the invention, it should be understood that other embodiments may be realized and that logical and mechanical changes may be made without departing from the spirit and scope of the invention. Thus, the detailed description herein is presented for purposes of illustration only and not of limitation. For example, the steps recited in any of the method or process descriptions may be executed in any order and are not limited to the order presented.

Moreover, it should be appreciated that the particular implementations shown and described herein are illustrative of the invention and its best mode and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

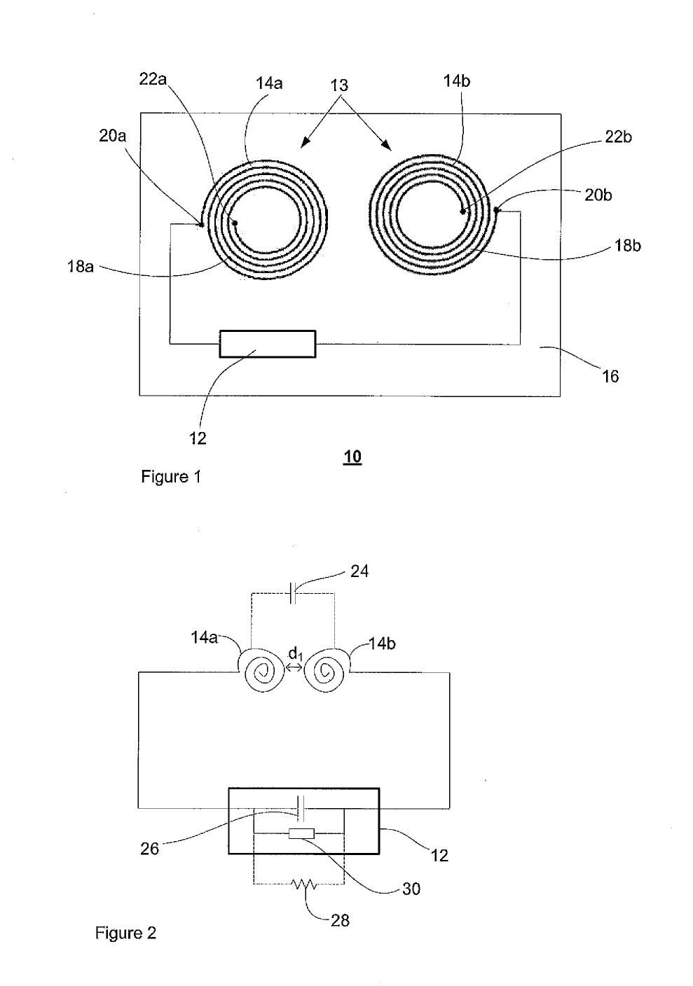

FIG. 1 shows an exemplary tag, generally identified by reference numeral 10, having a component, such as a chip 12, coupled to an antenna assembly 13 having antenna elements 14a, 14b on a substrate 16. Antenna elements 14a, 14b comprise a planar conductive pattern 18a and 18b, respectively, generally formed of spiral coils. A first end 20a of the conductive pattern 18a is coupled to chip 12, and a second end 22a of the conductive pattern 18a is free of any electrical coupling; and correspondingly a first end 20b of the conductive pattern 18b is coupled to chip 12, and a second end 22b of the conductive pattern 18b is free of any electrical coupling. The inductive and capacitive printed coils 18a, 18b are separated on substrate 16 by a predetermined distance d₁, geometrically combine to optimally couple a high frequency signal from tag reader (not shown) to the chip 12 in an NFC/RFID application. In addition to providing a means of efficient coupling, this design configuration also obviates the need for a bridged connection from second ends 22a and 22b to the chip 12. The substrate 16 may be flexible, and may be folded to bring antenna elements 14a, 14b together, thus enhancing the capacitive coupling.

Looking now at an equivalent circuit diagram in FIG. 2, it can be seen that the geometry of antenna coils 18a, 18b give rise to a capacitance, including parasitic capacitances, that is, C_{coils+parasitics}, denoted by numeral 24. Chip 12 also contributes a capacitance C_{chip} denoted by reference numeral 26 and a chip load, resistance R, denoted by reference numeral 28, inductance L, denoted by reference numeral 30. Accordingly, C_{coils+parasitics} 24 and C_{chip} 26 are coupled together in a series configuration.

Schematically, the tag antenna is modeled as a geometric printable planar inductive, capacitive, resistive, serial, parallel circuit array that is geometrically positioned and surface sized to create separate component values. As a result, many unique form factors are possible, and therefore uniquely modeled printable NFC/RFID tags can be achieved. Accordingly, bridgeless tag 10 may be used in radio frequency identification (RFD) systems and near-field communication (NFC) systems at typical frequencies of 125 kHz or 13.56 MHz, via inductive and/or capacitive coupling, however, other frequencies in the LF band, HF band, UHF band and SHF band are applicable.

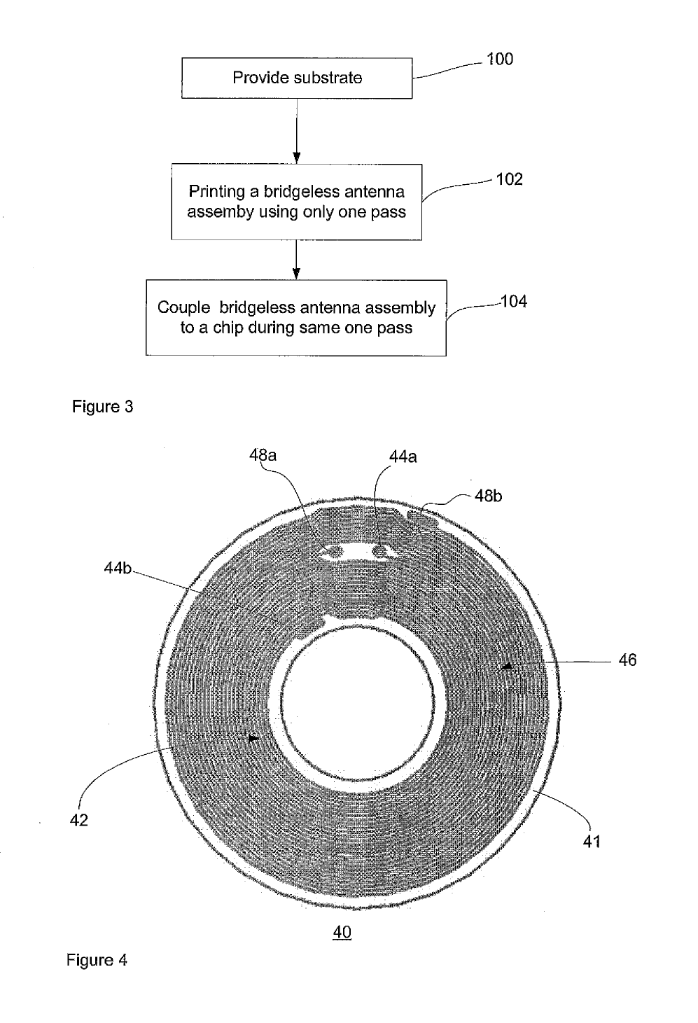

The method of manufacture of a bridgeless tag 10 will now be described with reference to a flow diagram of FIG. 3, and FIG. 2. The method includes the steps of providing a substrate having a surface (step 100), such as a roll or sheet of polymer substrate 16; depositing, in one pass, a bridgeless antenna assembly 13 comprising a first conductive trace 18a with one antenna lead 20a connected to circuitry 12 and another antenna lead 22a free of any permanent physical coupling and a second conductive trace 18b with one antenna lead 20b connected to circuitry 12 and another antenna lead 22b free of any permanent physical coupling (step 102). This method can be used to manufacture bridgeless antennas 14a, 14b in which conductive material is deposited onto the substrate 16 form an antenna pattern 18a, 18b on the substrate 16, such as vacuum metallization, conductive ink printing and standard print and etching processes. A plurality of antenna form factors are also possible, and depend on the target application and operating environment. For example, substrate 16 may be a polymer such as ETFE, FEP, PA, PE, PET, PFA, PI, PVC, SI, XL; or paper, polycarbonate, ABS or impregnated paper, carbon-fiber-reinforced polymer, epoxy glass or polyimide substrates etc., with varying dimensions; and the conductive pattern 18 is formed by means of an electrically conductive ink comprising copper, silver, gold, palladium, tin or alloys of these elements, among others.

In step 104, circuitry 12 is applied to substrate 16 and ends 20a, 20b of conductive traces 18a, 18b of the antenna assembly 13 are coupled to circuitry 12 to form a bridgeless tag 10. Step 102 and 104 are performed in a single pass. Accordingly, the bridgeless antenna design substantially mitigates the above-noted issues with multi-pass manufacturing techniques, and substantially simplifies manufacturing by enabling roll to roll production to be realized. Other benefits include minimal interconnections to the relatively easily mountable component 12. Also, a bridgeless antenna 10 is substantially more resistant to the stresses experienced in the lifetime of the product as there are reduced concerns over the integrity of any bond between the antenna leads and the component.

FIG. 4 shows an exemplary antenna 40 formed on a substrate 41, and comprising an inner coil or printed conductive pattern 42 having one lead 44a connectable to electronic circuitry such as an integrated circuit or chip (not shown) and a connection-free lead 44b, and an outer coil or printed conductive pattern 46 having one lead 48a connectable to electronic circuitry such as an integrated circuit or chip (not shown) and a connection-free lead 48b. Accordingly, the inner coil or printed conductive pattern 42 and outer coil or printed conductive pattern 46 may be connected in series by the integrated circuit or chip, between lead 44a and lead 48a. As such, an RFID tag or NFC tag comprising a bridgeless antenna 40 may be achieved. Further, the two series connected elements 42, 46 may be capacitively coupled in order to complete the circuit between connection-free leads 44b and 48b when printed on an anti-static substrate, or when an antistatic adhesive is applied over the elements 42, 46, or when introduced into an antistatic emulsion type dip. For example, the antistatic substrate or adhesive is chosen to have a conductance conductivity of about 500,000 ohms per square for a NFC tag which operates at 13.56 MHz, and provides a parasitic capacitive coupling to elements 42 and 46, and provides a completion to the full circuit. The capacitance between elements 42, 46 and the substrate is in a range of 100 pF to 120 pF, which in conjunction with the inductance provided by elements 42, 46 results in a resonant circuit tuned to a desired carrier frequency. Therefore, there is no need for physical connection or bridge from connection-free leads 44b and 48b to the electronic circuitry.

The bridgeless geometry provides an alternative to prior art antennas while achieving satisfactory performance for the RF air-interface in countless NFC/RFID applications while still achieving substantial manufacturing savings compared to prior art methods.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises,” “comprising,” or any other variations thereof; are intended to cover a non-exclusive inclusion, such that a process, method, article, or apparatus that comprises a list of elements does not include only those elements but may include other elements not expressly listed or inherent to such process, method, article, or apparatus. Further, no element described herein is required for the practice of the invention unless expressly described as “essential” or “critical.”

The preceding detailed description of exemplary embodiments of the invention makes reference to the accompanying drawings, which show the exemplary embodiment by way of illustration. For example, a person of ordinary skill in the art will recognize that the methods of the present invention are equally applicable to active RFID tags. In such embodiments, the same antenna assembly 13 of the invention may be used, and the primary difference in the tag 10 will be the inclusion of a power source (e.g., battery) and related circuitry.

While these exemplary embodiments are described in sufficient detail to enable those skilled in the art to practice the invention, it should be understood that other embodiments may be realized and that logical and mechanical changes may be made without departing from the spirit and scope of the invention. For example, the steps recited in any of the method or process claims may be executed in any order and are not limited to the order presented, Further, the present invention may be practiced using one or more servers, as necessary. Thus, the preceding detailed description is presented for purposes of illustration only and not of limitation, and the scope of the invention is defined by the preceding description, and with respect to the attached claims.

The embodiments of the invention in which an exclusive property or privilege is claimed are defined as follows:

1. A method of manufacture of a tag, the method comprising the steps of
providing a substrate having a surface;
in one pass, depositing conductive material on said surface to form an antenna assembly having a first conductive trace with one antenna lead connected to electronic circuitry and another antenna lead free of any coupling, and a second conductive trace with one antenna lead connected to said electronic circuitry and another antenna lead free of any coupling.

2. The method of claim 1, wherein said first conductive trace and second conductive trace are separated by a predetermined distance, said distance selected to achieve a resonant frequency corresponding to a desired carrier frequency.

3. The method of claim 2, wherein capacitive coupling between said first conductive trace and said second conductive trace and said substrate completes a circuit formed of said first conductive trace, second conductive trace and said electronic circuitry to obviate a physical electrical connection from said leads free of any coupling to said electronic circuitry, thereby resulting in said tag having a bridgeless antenna.

4. The method of claim 3, wherein said first conductive trace, second conductive trace and electronic circuitry comprise inductive elements, capacitive elements and resistive elements to form a resonant LC antenna tuned to a desired carrier frequency, and said antenna having predetermined quality (Q) factor.

5. The method of claim 4, wherein said carrier frequency is selected for at least one of a LF band, HF band, UHF band and a SHF band.

6. The method of claim 5, wherein said tag is operated as a component in at least one of a radio frequency identification (RFID) communication system and a near-field communication (NFC) system via inductive and/or capacitive coupling.

7. The method of claim 6, wherein said substrate comprises at least one of an antistatic adhesive and an emulsion with antistatic agents.

8. The method of claim 7, wherein said conductive trace is deposited onto the substrate via at least one of a vacuum metallization process, conductive ink printing process, and a print and etching process.

9. The method of claim 8, wherein said conductive trace comprises a conductive material chosen from at least one of copper, silver, gold, palladium, tin or alloys thereof.

10. The method of claim 9, wherein said substrate comprises at least one of a polymer, paper, polycarbonate, ABS or impregnated paper, carbon-fiber-reinforced polymer, epoxy glass or polyimide substrate.

11. An antenna comprising:
a substrate having a surface;
a bridgeless antenna assembly on said surface, and said bridgeless antenna assembly comprising a first conductive trace with one antenna lead for connection to circuitry and another antenna lead free of any permanent physical coupling and a second conductive trace with one antenna lead for connection to circuitry and another antenna lead free of any permanent physical connection.

12. The antenna of claim 11, wherein said first conductive trace and second conductive trace are deposited on said substrate and said antenna leads are coupled to said circuitry in one pass.

13. The antenna of claim 12, wherein said first conductive trace and second conductive trace are separated by a predetermined distance, said distance selected to achieve a resonant frequency corresponding to a desired carrier frequency.

14. The antenna of claim 13, wherein capacitive coupling between said first conductive trace and said second conductive trace and said substrate provides a completion to a full circuit formed of said first conductive trace, second conductive trace and said electronic circuitry to obviate a physical electrical connection from said leads free of any coupling to said electronic circuitry, thereby resulting in a bridgeless antenna.

15. The antenna of claim 14, wherein said first conductive trace, second conductive trace and electronic circuitry comprise inductive elements, capacitive elements and resistive elements to form a resonant LC antenna tuned to a desired carrier frequency, and said antenna having predetermined quality (Q) factor.

16. The antenna of claim 15, wherein at said carrier frequency of 13.56 MHz said substrate comprises a conductance of about 500,000 ohms per square and parasitic capacitance between said first conductive trace, said second conductive trace and said substrate is in a range of 100 pF to 120 pF; and
wherein said substrate comprises at least one of an antistatic adhesive and an emulsion with antistatic agents.

17. A tag having:
circuitry;
an antenna assembly comprising a first conductive trace with one antenna lead connected to said circuitry and another antenna lead free of any permanent physical coupling and a second conductive trace with one antenna lead connected to said circuitry and another antenna lead free of any permanent physical connection; and
wherein capacitive coupling between said first conductive trace and said second conductive trace and said substrate completes a circuit formed of said first conductive trace, second conductive trace and said circuitry to obviate a physical electrical connection from said leads free of any coupling to said circuitry, thereby resulting in said tag having a bridgeless antenna assembly.

18. The tag of claim 17, wherein said first conductive trace and second conductive trace are deposited on a substrate and said antenna leads are coupled to said circuitry in one pass, and said first conductive trace and second conductive trace are separated by a predetermined distance, said distance selected to achieve a resonant frequency corresponding to a desired carrier frequency.

19. The tag of claim 17, wherein said first conductive trace, second conductive trace and electronic circuitry comprise inductive elements, capacitive elements and resistive elements to form a resonant LC antenna tuned to a desired carrier frequency, and said antenna having predetermined quality (Q) factor.

20. A method of manufacture of an antenna assembly, the method comprising the steps of:
providing a substrate having a surface;
depositing in one pass a conductive pattern on said surface, said conductive pattern having a first conductive trace with a first antenna lead for coupling to a component and a second connection-free antenna lead; and having a second conductive trace with a first antenna lead for coupling to said component and a second connection-free antenna lead;
wherein capacitive coupling between said first conductive trace and said second conductive trace and said substrate completes a circuit formed of said first conductive trace, second conductive trace and said component to obviate a physical electrical connection from said second connection-free antenna leads to said component, thereby resulting in a bridgeless antenna assembly.
